(19) United States
(12) Patent Application Publication
(10) Pub. No.: US 2024/0179973 A1
(43) Pub. Date: May 30, 2024

(54) DISPLAY PANEL AND DISPLAY APPARATUS

(71) Applicant: BOE Technology Group Co., Ltd., Beijing (CN)

(72) Inventors: Guangliang Shang, Beijing (CN); Hao Liu, Beijing (CN); Jiangnan Lu, Beijing (CN); Mengyang Wen, Beijing (CN); Xinbin Han, Beijing (CN)

(73) Assignee: BOE Technology Group Co., Ltd., Beijing (CN)

(21) Appl. No.: 18/264,484

(22) PCT Filed: Nov. 25, 2022
(86) PCT No.: PCT/CN2022/134226

§ 371 Date: Aug. 7, 2023

(51) Int. Cl. H10K 59/131

(52) U.S. Cl. CPC H10K 59/131

(57) ABSTRACT

A display panel is provided. The display panel includes a display area and a peripheral area. The peripheral area includes a first region, a second region, a third region, and a fourth region. The second region includes a scan circuit configured to generate control signals for subpixels in the display area. The third region includes a voltage supply pad configured to provide a voltage supply signal to the subpixels in the display area. The first region includes fanout lines connecting the scan circuit to the subpixels in the display area. The fourth region includes one or more sub-regions.

### TECHNICAL FIELD

The present invention relates to display technology, more particularly, to a display panel and a display apparatus.

### BACKGROUND

Organic light emitting diode (OLED) display apparatuses are self-emissive devices, and do not require backlights. OLED display apparatuses also provide more vivid colors and a larger color gamut as compared to the conventional liquid crystal display (LCD) apparatuses. Further, OLED display apparatuses can be made more flexible, thinner, and lighter than a typical LCD apparatus. An OLED display apparatus typically includes an anode, an organic layer including a light emitting layer, and a cathode. OLEDs can be either a bottom-emission type OLED or a top-emission type OLED.

### SUMMARY

In one aspect, the present disclosure provides a display panel having a display area and a peripheral area, wherein the peripheral area comprises a first region, a second region, a third region, and a fourth region; the second region comprises a scan circuit configured to generate control signals for subpixels in the display area; the third region comprises a voltage supply pad configured to provide a voltage supply signal to the subpixels in the display area; the first region comprises fanout lines connecting the scan circuit to the subpixels in the display area; and the fourth region comprises one or more sub-regions.

Optionally, the fanout lines connect to the scan circuit at a first connecting interface and connect to the display area at a second connecting interface; and a first width of the first connecting interface is less than a second width of the second connecting interface.

Optionally, the scan circuit has a non-uniform inter-unit distance; in a first portion of the scan circuit adjacent to at least one sub-region of the one or more sub-regions, the scan circuit has a first average inter-unit distance; in a second portion of the scan circuit that is not directly adjacent to the one or more sub-regions, the scan circuit has a second average inter-unit distance; and the second average inter-unit distance is greater than the first average inter-unit distance.

Optionally, the second region comprises a plurality of scan unit areas and one or more connecting line areas; the scan circuit comprises a plurality of scan units in cascading stages; a respective scan unit of the plurality of scan units comprises transistors; the transistors of the scan circuit is absent in the one or more connecting line areas; the one or more connecting line areas comprises only signal lines; a respective connecting line area of the one or more connecting line areas comprises signal lines connecting scan units of adjacent stages and respectively in two adjacent scan unit areas of the plurality of scan unit areas.

Optionally, the fanout lines connect to the scan circuit through the plurality of scan units in the plurality of scan unit areas, and do not directly connect to the one or more connecting line areas; a first connecting interface is between the first region and the plurality of scan unit areas; and the first connecting interface is absent in regions corresponding to the one or more connecting line areas.

Optionally, at least one sub-region of the one or more sub-regions of the fourth region is surrounded by a combination of the first region and the second region.

Optionally, two scan unit areas of the plurality of scan unit areas are respectively on a first side and on a second side of a respective sub-region of the one or more sub-regions, the first side and the second side being opposite to each other; and a portion of the first region is on a third side of the respective sub-region, a respective connecting line area of the one or more connecting line areas is on a fourth side of the respective sub-region, the third side and the fourth side being opposite to each other.

Optionally, a first sub-region of the one or more sub-regions is on one side of at least one scan unit area of the plurality of scan unit areas; and a second sub-region of the one or more sub-regions is on an opposite side of the at least one scan unit area.

Optionally, the plurality of scan unit areas and at least one of the one or more sub-regions are arranged in a same column.

Optionally, signal lines in the respective connecting line area of the one or more connecting line areas curve around at least one sub-region of the one or more sub-regions.

Optionally, the one or more sub-regions comprise a first respective sub-region and a second respective sub-region; the first respective sub-region is surrounded by a combination of the first region and the second region; two scan unit areas of the plurality of scan unit areas are respectively on a first side and on a second side of the first respective sub-region, the first side and the second side being opposite to each other; a portion of the first region is on a third side of the first respective sub-region; a respective connecting line area of the one or more connecting line areas is on a fourth side of the first respective sub-region, the third side and the fourth side being opposite to each other; the third region is on a first side, a second side, and a fourth side of the second respective sub-region; and a respective scan unit area of the plurality of scan unit areas is on a third side of the second respective sub-region.

Optionally, the third region comprises a main area and a surrounding area; the main area is on a side of the second region away from the display area; the one or more sub-regions comprises a first respective sub-region; the surrounding area substantially surrounds the first respective sub-region; and the voltage supply pad are at least partially present in the surrounding area.

Optionally, the third region comprises a plurality of straight line areas and one or more curved line areas; signal lines in the plurality of straight line areas extend substantially along a same extension direction; signal lines in the one or more curved line areas are curved signal lines; and signal lines in a respective curved line area of the one or more curved line areas connect signal lines in two adjacent straight line areas of the plurality of straight line areas.

Optionally, two straight line areas of the plurality of straight line areas are respectively on a first side and on a second side of a respective sub-region of the one or more sub-regions, the first side and the second side being opposite to each other; and a respective curved line area of the one or more curved line areas is on a third side of the respective sub-region.

Optionally, a first sub-region of the one or more sub-regions is on one side of at least one straight line area of the plurality of straight line areas; and a second sub-region of the one or more sub-regions is on an opposite side of the at least one straight line area.

Optionally, the plurality of straight line areas and at least one of the one or more sub-regions are arranged in a same column.

Optionally, signal lines in the respective curved line area of the one or more curved line areas curve around a side of at least one sub-region of the one or more sub-regions; and signal lines in a respective connecting line area of the one or more connecting line areas curve around the signal lines in the respective curved line area of the one or more curved line areas.

Optionally, the one or more sub-regions comprise a first respective sub-region and a second respective sub-region; two straight line areas of the plurality of straight line areas are respectively on a first side and on a second side of the first respective sub-region, the first side and the second side being opposite to each other; a respective curved line area of the one or more curved line areas is on a third side of the first respective sub-region; the fourth region further comprises a margin area on a side of the first respective sub-region and the second respective sub-region away from the display area; the margin area is on a fourth side of the first respective sub-region; the margin area is on a first side, a second side, and a fourth side of the second respective sub-region; and a respective straight line area of the plurality of straight line areas is on a third side of the second respective sub-region.

Optionally, the display panel further comprises an encapsulating layer extending from the display area into the peripheral area; wherein the encapsulating layer encapsulates light emitting elements and circuits in the display panel; the encapsulating layer extends throughout the display area; the encapsulating layer is at least partially present in the first region, the second region, and the third region; and the encapsulating layer is at least partially absent in the fourth region.

Optionally, display area, the first region, the second region, and the third region are sequentially arranged along a direction away from the display area.

In another aspect, the present disclosure provides a display apparatus, comprising the display panel described herein, and one or more integrated circuits connected to the display panel.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of a related display panel.

FIG. 2 is a schematic diagram illustrating the structure of a portion of a related display panel.

FIG. 3A is a schematic diagram illustrating the structure of a portion of a display panel in some embodiments according to the present disclosure.

FIG. 3B illustrates a first region in a display panel in some embodiments according to the present disclosure.

FIG. 3C illustrates a second region in a display panel in some embodiments according to the present disclosure.

FIG. 3D illustrates a respective sub-region in a display panel in some embodiments according to the present disclosure.

FIG. 4A is a schematic diagram illustrating the structure of a scan circuit in some embodiments according to the present disclosure.

FIG. 4B is a schematic diagram illustrating the structure of a scan circuit in some embodiments according to the present disclosure.

FIG. 5A is a schematic diagram illustrating the structure of a portion of a display panel in some embodiments according to the present disclosure.

FIG. 5B illustrates a first region in a display panel in some embodiments according to the present disclosure.

FIG. 5C illustrates a second region in a display panel in some embodiments according to the present disclosure.

FIG. 5D illustrates a third region in a display panel in some embodiments according to the present disclosure.

FIG. 5E illustrates a respective sub-region in a display panel in some embodiments according to the present disclosure.

FIG. 6A is a schematic diagram illustrating the structure of a portion of a display panel in some embodiments according to the present disclosure.

FIG. 6B illustrates a first region in a display panel in some embodiments according to the present disclosure.

FIG. 6C illustrates a second region in a display panel in some embodiments according to the present disclosure.

FIG. 6D illustrates a third region in a display panel in some embodiments according to the present disclosure.

FIG. 6E illustrates a first respective sub-region in a display panel in some embodiments according to the present disclosure.

FIG. 6F illustrates a second respective sub-region in a display panel in some embodiments according to the present disclosure.

FIG. 7A is a schematic diagram illustrating the structure of a portion of a display panel in some embodiments according to the present disclosure.

FIG. 7B illustrates a first region in a display panel in some embodiments according to the present disclosure.

FIG. 7C illustrates a second region in a display panel in some embodiments according to the present disclosure.

FIG. 7D illustrates a first respective sub-region in a display panel in some embodiments according to the present disclosure.

FIG. 7E illustrates a second respective sub-region in a display panel in some embodiments according to the present disclosure.

FIG. 8A is a schematic diagram illustrating the structure of a portion of a display panel in some embodiments according to the present disclosure.

FIG. 8B illustrates a first region in a display panel in some embodiments according to the present disclosure.

FIG. 8C illustrates a second region in a display panel in some embodiments according to the present disclosure.

FIG. 8D illustrates a third region in a display panel in some embodiments according to the present disclosure.

FIG. 8E illustrates a respective sub-region in a display panel in some embodiments according to the present disclosure.

FIG. 9 is a schematic diagram illustrating a layout of fanout lines relative to one or more sub-regions in a display panel in some embodiments according to the present disclosure.

FIG. 10 illustrates an overall shape of multiple fanout lines in a portion of a first region in a display panel in some embodiments according to the present disclosure.

FIG. 11 illustrates the structure of multiple fanout lines in a portion of a first region in a display panel in some embodiments according to the present disclosure.

FIG. 12 illustrates the structure of multiple fanout lines in a portion of a first region in a display panel in some embodiments according to the present disclosure.

FIG. 13 illustrates a detailed structure in a display area in a display panel in some embodiments according to the present disclosure.

FIG. 14 illustrates the structure of curved signal lines in a portion of a first region in a display panel in some embodiments according to the present disclosure.

FIG. 15 illustrates the structure of curved signal lines in a portion of a first region in a display panel in some embodiments according to the present disclosure.

FIG. 16 illustrates the structure of curved signal lines in a portion of a first region in a display panel in some embodiments according to the present disclosure.

FIG. 17 illustrates different loading in different fanout lines in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

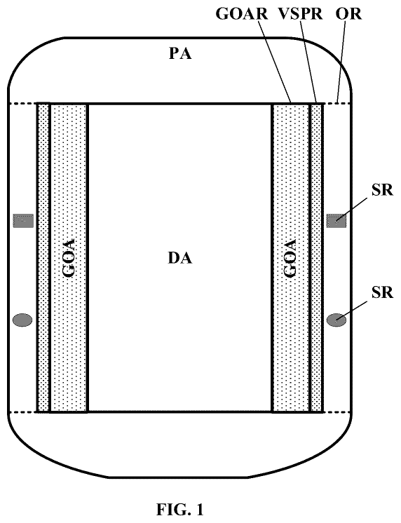

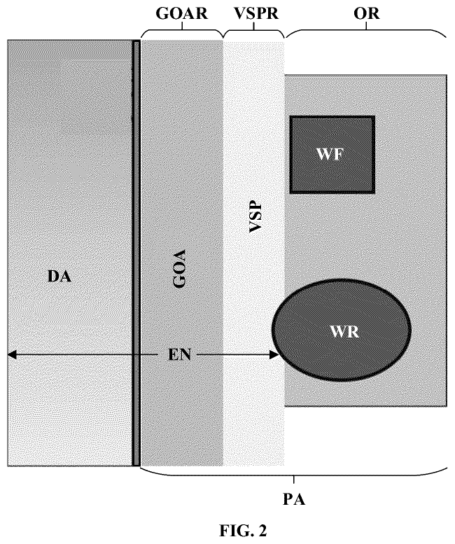

FIG. 1 is a schematic diagram illustrating the structure of a related display panel. FIG. 2 is a schematic diagram illustrating the structure of a portion of a related display panel. Referring to FIG. 1 and FIG. 2, the display panel includes a display area DA and a peripheral area PA. As used herein, the term “display area” refers to an area of a display where image is actually displayed. Optionally, the display area may include both a subpixel region and an inter-subpixel region. A subpixel region refers to a light emission region of a subpixel, such as a region corresponding to a pixel electrode in a liquid crystal display or a region corresponding to a light emissive layer in an organic light emitting diode display panel. An inter-subpixel region refers to a region between adjacent subpixel regions, such as a region corresponding to a black matrix in a liquid crystal display or a region corresponding to a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels. As used herein the term “peripheral area” refers to an area of a display panel where various circuits and wires are provided to transmit signals to the display substrate. To increase the transparency of the display apparatus, non-transparent or opaque components of the display apparatus (e.g., battery, printed circuit board, metal frame), can be disposed in the peripheral area rather than in the display areas.

As shown in FIG. 1 and FIG. 2, the peripheral area PA in some embodiments includes a gate-on-array region GOAR, a voltage supply pad region VSPR, and an outer region OR. In some embodiments, a gate-on-array GOA is disposed in the gate-on-array region GOAR. In some embodiments, a voltage supply pad VSP is disposed in the voltage supply pad region VSPR. In some embodiments, the voltage supply pad VSP is configured to provide a voltage supply signal (e.g., a Vss signal) to the subpixels in the display area DA.

In some embodiments, the display panel further includes an encapsulating layer EN encapsulating light emitting elements and circuits in the display panel. In some embodiments, the encapsulating layer extends throughout the display area DA, the gate-on-array region GOAR, and the voltage supply pad region VSPR. Optionally, the encapsulating layer is at least partially (e.g., completely) absent in the outer region OR.

In some embodiments, the outer region OR includes a window sub-region WR in which at least one layer in the display area DA is absent and/or a touch control layer is absent. In one example, the display panel further includes an accessory installed in the window sub-region WR. In one example, there is a hole (through-hole or a blind hole) in the window sub-region WR. Examples of accessories include a camera lens and a fingerprint sensor. In some embodiments, the outer region OR further includes a wire-free sub-region WF in which signal lines are absent.

As shown in FIG. 1 and FIG. 2, in the related display panel, the outer region OR (including the window sub-region WR and/or the wire-free sub-region WF) is on a side of the voltage supply pad region VSPR away from the gate-on-array region GOAR. The gate-on-array region GOAR, the voltage supply pad region VSPR, and the outer region OR are sequentially arranged along a direction away from the display area DA. A relatively large bezel area is required in the related display panel to accommodate the components.

Accordingly, the present disclosure provides, inter alia, a display panel and a display apparatus that substantially obviate one or more of the problems due to limitations and disadvantages of the related art. In one aspect, the present disclosure provides a display panel. In some embodiments, the display panel includes a display area and a peripheral area. Optionally, the peripheral area includes a first region, a second region, a third region, and a fourth region. Optionally, the second region comprises a scan circuit configured to generate control signals for subpixels in the display area. Optionally, the third region comprises a voltage supply pad configured to provide a voltage supply signal to the subpixels in the display area. Optionally, the first region comprises fanout lines connecting the scan circuit to the subpixels in the display area. Optionally, the fourth region comprises one or more sub-regions.

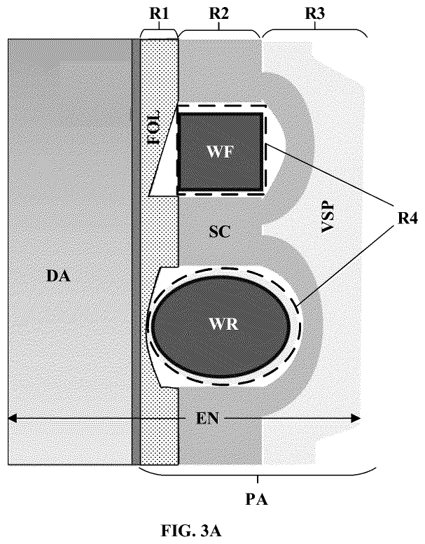

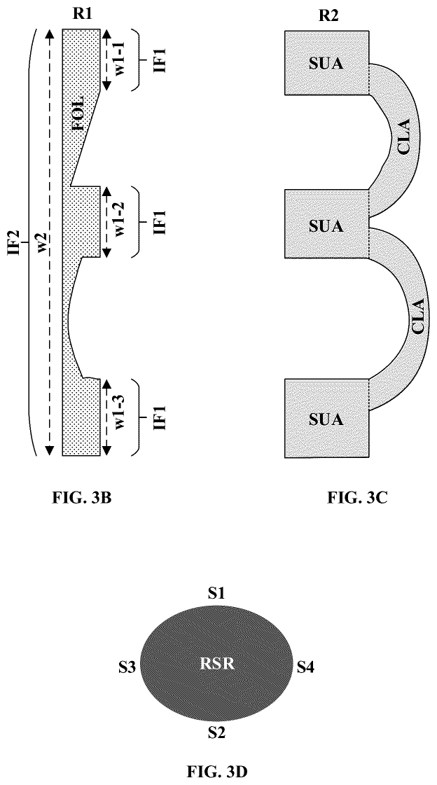

FIG. 3A is a schematic diagram illustrating the structure of a portion of a display panel in some embodiments according to the present disclosure. Referring to FIG. 3A, the peripheral area PA in some embodiments includes a first region R1, a second region R2, a third region R3, and a fourth region R4. The display area DA, the first region R1, the second region R2, and the third region R3 are sequentially arranged along a direction away from the display area DA. The first region R1 is between the display area DA and the second region R2. The second region R2 is between the first region R1 and the third region R3. The first region R1 spaces apart the display area DA and the second region R2. The second region R2 spaces apart the first region R1 and the third region R3.

In some embodiments, the second region R2 includes a scan circuit SC (e.g., a gate-on-array). Various appropriate scan circuits may be disposed in the second region R2. Examples of scan circuits include a gate scanning signal generating circuit configured to generate gate scanning signals for subpixels in a display panel (e.g., a gate-on-array), a reset control signal generating circuit configured to generate reset control signals for subpixels in a display panel, a light emitting control signal generating circuit configured to generate light emitting control signals for subpixels in a display panel, and any combination thereof.

In some embodiments, the third region R3 includes a voltage supply pad configured to provide a voltage supply signal to the subpixels in the display area DA. In one example, the voltage supply pad is configured to provide a voltage (e.g., a Vss voltage) to cathodes of the subpixels in the display area DA. In another example, the voltage supply pad is configured to provide a high voltage (e.g., a Vdd voltage) to the subpixels in the display area DA.

The first region R1 includes fanout lines FOL connecting the scan circuits to the subpixels in the display area DA. As used herein, the term “fanout” refers to that a first width of a first connecting interface at which fanout lines FOL connect to the scan circuit SC is less than a second width of a second connecting interface at which fanout lines FOL connect to the display area DA. A ratio of the second width to the first width is greater than 1, e.g., greater than 1.1, greater than 1.2, greater than 1.3, greater than 1.4, greater than 1.5, greater than 2.0, greater than 2.5, greater than 3.0, greater than 3.5, greater than 4.0, greater than 4.5, or greater than 5.0.

The fourth region R4 includes one or more sub-regions. In one example, the one or more sub-regions include a window sub-region WR having a hole. In another example, the one or more sub-regions include a wire-free sub-region WF. In the window sub-region WR, at least one layer in the display area DA is absent and/or a touch control layer is absent. In one example, the display panel further includes an accessory installed in the window sub-region WR. In one example, there is a hole (through-hole or a blind hole) in the window sub-region WR. Examples of accessories include a camera lens and a fingerprint sensor. In the wire-free sub-region WF, signal lines are absent.

In some embodiments, an encapsulating layer EN extends from the display area DA into the peripheral area PA. The encapsulating layer EN encapsulates light emitting elements and circuits in the display panel. The encapsulating layer EN extends throughout the display area DA. The encapsulating layer EN is at least partially present in the first region R1, the second region R2, and the third region R3. The encapsulating layer EN is at least partially absent (e.g., completely absent) in the fourth region R4.

FIG. 3B illustrates a first region in a display panel in some embodiments according to the present disclosure. Referring to FIG. 3A and FIG. 3B, a first connecting interface IF1 at which fanout lines FOL connect to the scan circuit SC and a second connecting interface IF2 at which fanout lines FOL connect to the display area DA are depicted. A first width of the first connecting interface IF1 is less than the second width w2 of the second connecting interface IF2. The first width is a sum of w1-1, w1-2, and w1-3 depicted in FIG. 3B. A ratio of the second width w2 to the first width is greater than 1, e.g., greater than 1.1, greater than 1.2, greater than 1.3, greater than 1.4, greater than 1.5, greater than 2.0, greater than 2.5, greater than 3.0, greater than 3.5, greater than 4.0, greater than 4.5, or greater than 5.0.

FIG. 3C illustrates a second region in a display panel in some embodiments according to the present disclosure. Referring to FIG. 3C, the second region R2 in some embodiments includes a plurality of scan unit areas SUA and one or more connecting line areas CLA. The scan circuit includes a plurality of scan units in cascading stages. A respective scan unit of the plurality of scan units includes transistors. The transistors of the scan circuit is absent in the one or more connecting line areas CLA. The one or more connecting line areas CLA include only signal lines. A respective connecting line area of the one or more connecting line areas CLA includes signal lines connecting scan units of adjacent stages and respectively in two adjacent scan unit areas of the plurality of scan unit areas SUA.

In some embodiments, as shown in FIG. 3A to FIG. 3C, the fanout lines FOL connect to the scan circuit through the scan units in the plurality of scan unit areas SUA, and do not directly connect to the one or more connecting line areas CLA. The first connecting interface IF1 is between the first region R1 and the plurality of scan unit areas SUA, and the first connecting interface IF1 is absent in regions corresponding to the one or more connecting line areas CLA.

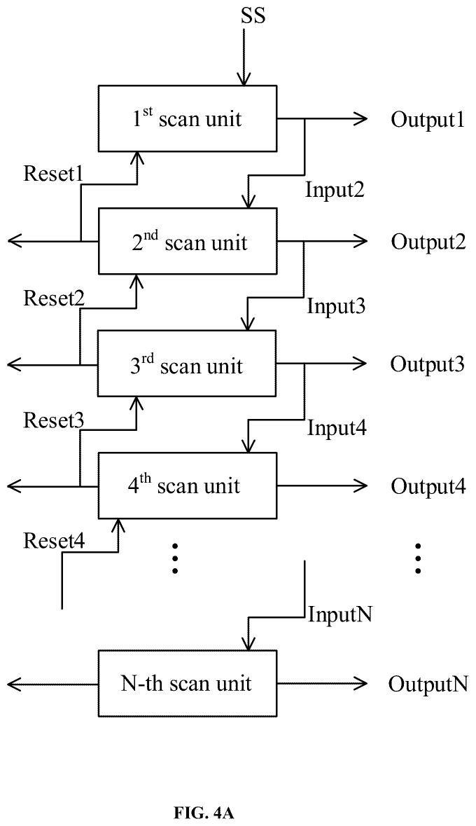

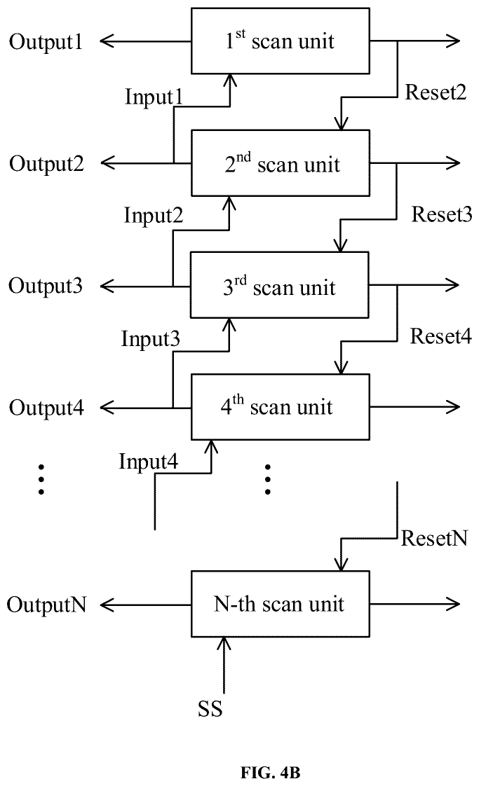

FIG. 4A is a schematic diagram illustrating the structure of a scan circuit in some embodiments according to the present disclosure. Referring to FIG. 4A, the scan circuit in some embodiments includes N number of stages. A respective stage of the N number of stages includes a respective scan unit. As depicted in FIG. 4A, the scan circuit includes a 1^{st} scan unit, a 2^{nd} scan unit, a 3^{rd} scan unit, a 4^{th} scan unit, . . . , an N-th scan unit. The N number of scan units are configured to provide N number of control signals (e.g., gate signals, reset control signals, or light emission control signals) to N number of rows of subpixels. The N number of control signals are denoted as Output1, Output2, Output3, Output4, . . . , OutputN in FIG. 4A. An n-th scan unit is configured to receive a start signal SS or an output signal from an output terminal of a previous scan unit (e.g., a (n−1)-th scan unit, a (n−2)-th scan unit, or a (n−3)-th scan unit). As used herein, the term “previous scan unit” is not limited to immediately previous scan unit (e.g., the (n−1)-th scan unit), but includes any appropriate previous scan unit (e.g., the (n−2)-th scan unit, or the (n−3)-th scan unit). In FIG. 4A, the 1^{st} scan unit is configured to receive the start signal SS as the input signal, the 2^{nd} scan unit is configured to receive an output signal from the 1^{st} scan unit as an input signal Input2, the 3^{rd} scan unit is configured to receive an output signal from the 2^{nd} scan unit as an input signal Input3, the 4^{th} scan unit is configured to receive an output signal from the 3^{rd} scan unit as an input signal Input4, the N-th scan unit is configured to receive an output signal from the (N−1)-th scan unit as an input signal InputN.

Referring to FIG. 4A, an n-th scan unit is configured to receive an output signal from a subsequent scan unit (e.g., a (n+1)-th scan unit, a (n+2)-th scan unit, or a (n+3)-th scan unit) as a reset signal. As used herein, the term “subsequent scan unit” is not limited to immediately subsequent scan unit (e.g., the (n+1)-th scan unit), but includes any appropriate subsequent scan unit (e.g., the (n+2)-th scan unit, or the (n+3)-th scan unit). In FIG. 4A, the 1^{st} scan unit is configured to receive an output signal from the 2^{nd} scan unit as a reset signal Reset1, the 2^{nd} scan unit is configured to receive an output signal from the 3^{rd} scan unit as a reset signal Reset2, the 3^{rd} scan unit is configured to receive an output signal from the 4^{th} scan unit as a reset signal Reset3, and the 4^{th} scan unit is configured to receive an output signal from the 5^{th} scan unit as a reset signal Reset4.

In some embodiments, the scan circuit may be operated in a forward scanning mode and a reverse scanning mode. FIG. 4A illustrates the forward scanning mode of the scan circuit. FIG. 4B is a schematic diagram illustrating the structure of a scan circuit in some embodiments according to the present disclosure. FIG. 4B illustrates the reverse scanning mode of the scan circuit. Referring to FIG. 4B, an n-th scan unit is configured to receive a start signal SS or an output signal from an output terminal of a subsequent scan unit (e.g., a (n+1)-th scan unit, a (n+2)-th scan unit, or a (n+3)-th scan unit). In FIG. 4B, the N-th scan unit is configured to receive the start signal SS as the input signal, the 4^{th} scan unit is configured to receive an output signal from a 5^{th} scan unit as an input signal Input4, the 3rd scan unit is configured to receive an output signal from the 4^{th} scan unit as an input signal Input3, the 2^{nd} scan unit is configured to receive an output signal from the 3rd scan unit as an input signal Input2; and the 1^{st} scan unit is configured to receive an output signal from the 2^{nd} scan unit as an input signal Input1.

Referring to FIG. 4B, in the reverse scanning mode, an n-th scan unit is configured to receive an output signal from a previous scan unit (e.g., a (n−1)-th scan unit, a (n−2)-th scan unit, or a (n−3)-th scan unit) as a reset signal. In FIG. 4B, the 2^{nd} scan unit is configured to receive an output signal from the 1^{st} scan unit as a reset signal Reset2, the 3^{rd} scan unit is configured to receive an output signal from the 2^{nd} scan unit as a reset signal Reset3, the 4^{th} scan unit is configured to receive an output signal from the 3^{rd} scan unit as a reset signal Reset4, and the 5^{th} scan unit is configured to receive an output signal from the 4^{th} scan unit as a reset signal Reset5.

The 1^{st} scan unit to the N-th scan unit depicted in FIG. 4A and FIG. 4B are limited in the plurality of scan unit areas SUA. A respective connecting line area of the one or more connecting line areas CLA includes signal lines connecting scan units of adjacent stages and respectively in two adjacent scan unit areas of the plurality of scan unit areas SUA, for example, signal lines transmitting input signals or reset signals. The control signals (e.g., Output1, Output2, Output3, Output4, . . . , OutputN) are output to the fanout lines FOL in the first region R1, and transmitted to the display area DA through the fanout lines FOL.

Referring to FIG. 3A, in some embodiments, a respective sub-region of the one or more sub-regions (e.g., the window sub-region WR or the wire-free sub-region WF) of the fourth region R4 is surrounded by a combination of the first region R1 and the second region R2. FIG. 3D illustrates a respective sub-region in a display panel in some embodiments according to the present disclosure. Referring to FIG. 3A to FIG. 3D, two scan unit areas of the plurality of scan unit areas SUA are respectively on a first side S1 and on a second side S2 of the respective sub-region RSR, the first side S1 and the second side S2 being opposite to each other. A portion of the first region R1 is on a third side S3 of the respective sub-region RSR, a respective connecting line area of the one or more connecting line areas CLA is on a fourth side S4 of the respective sub-region RSR, the third side S3 and the fourth side S4 being opposite to each other.

In some embodiments, with regard to at least one scan unit area of the plurality of scan unit areas SUA, a first sub-region of the one or more sub-regions is on one side of the at least one scan unit area, and a second sub-region of the one or more sub-regions is on an opposite side of the at least one scan unit area.

In some embodiments, the plurality of scan unit areas SUA and the one or more sub-regions are arranged in a same column, e.g., substantially aligned along a same central line.

In some embodiments, signal lines in the respective connecting line area of the one or more connecting line areas CLA curve around the respective sub-region of the one or more sub-regions.

In some embodiments, the scan circuit has a non-uniform inter-unit distance. Optionally, in a first portion of the scan circuit adjacent to at least one (e.g., 1 or 2) sub-region of the one or more sub-regions, the scan circuit has a first average inter-unit distance; in a second portion of the scan circuit that is not directly adjacent to the one or more sub-regions, the scan circuit has a second average inter-unit distance. The second average inter-unit distance is greater than the first average inter-unit distance.

In the embodiments depicted in FIG. 3A, an overall smaller bezel area can be achieved as compared to the related display panel. Particularly, by having the one or more sub-regions disposed in a region between the first region R1 and the second region R2, the bezel area where the one or more sub-regions are located can be reduced. Due to the presence of the first region R1, the bezel area where the one or more sub-regions are absent is slightly increased, e.g., by 0.9 mm.

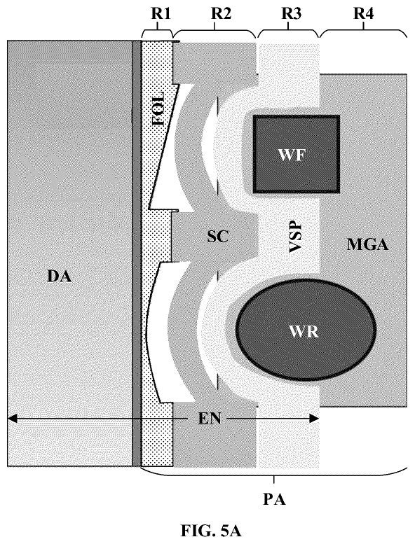

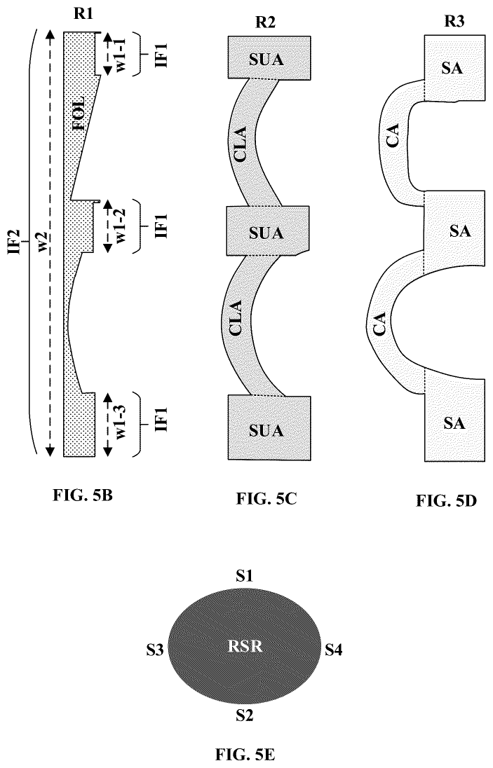

FIG. 5A is a schematic diagram illustrating the structure of a portion of a display panel in some embodiments according to the present disclosure. Referring to FIG. 5A, the peripheral area PA in some embodiments includes a first region R1, a second region R2, a third region R3, and a fourth region R4. The display area DA, the first region R1, the second region R2, and the third region R3 are sequentially arranged along a direction away from the display area DA. Optionally, the display area DA, the first region R1, the second region R2, the third region R3, and the fourth region R4 are sequentially arranged along a direction away from the display area DA. The first region R1 is between the display area DA and the second region R2. The second region R2 is between the first region R1 and the third region R3. The third region R3 is between the second region R2 and the fourth region R4. The first region R1 spaces apart the display area DA and the second region R2. The second region R2 spaces apart the first region R1 and the third region R3. The third region R3 spaces apart the second region R2 and the fourth region R4.

In some embodiments, the second region R2 includes a scan circuit SC. In some embodiments, the third region R3 includes a voltage supply pad configured to provide a voltage supply signal to the subpixels in the display area DA. The first region R1 includes fanout lines FOL connecting the scan circuits to the subpixels in the display area DA. The fourth region R4 includes one or more sub-regions, e.g., a window sub-region WR or a wire-free sub-region WF.

In some embodiments, an encapsulating layer EN extends from the display area DA into the peripheral area PA. The encapsulating layer EN encapsulates light emitting elements and circuits in the display panel. The encapsulating layer EN extends throughout the display area DA. The encapsulating layer EN is at least partially present in the first region R1, the second region R2, and the third region R3. The encapsulating layer EN is at least partially absent (e.g., completely absent) in the fourth region R4.

FIG. 5B illustrates a first region in a display panel in some embodiments according to the present disclosure. Referring to FIG. 5A and FIG. 5B, a first connecting interface IF1 at which fanout lines FOL connect to the scan circuit SC and a second connecting interface IF2 at which fanout lines FOL connect to the display area DA are depicted. A first width of the first connecting interface IF1 is less than the second width w2 of the second connecting interface IF2. The first width is a sum of w1-1, w1-2, and w1-3 depicted in FIG. 5B. A ratio of the second width w2 to the first width is greater than 1, e.g., greater than 1.1, greater than 1.2, greater than 1.3, greater than 1.4, greater than 1.5, greater than 2.0, greater than 2.5, greater than 3.0, greater than 3.5, greater than 4.0, greater than 4.5, or greater than 5.0.

FIG. 5C illustrates a second region in a display panel in some embodiments according to the present disclosure. Referring to FIG. 5C, the second region R2 in some embodiments includes a plurality of scan unit areas SUA and one or more connecting line areas CLA. The scan circuit includes a plurality of scan units in cascading stages. A respective scan unit of the plurality of scan units includes transistors. The transistors of the scan circuit is absent in the one or more connecting line areas CLA. The one or more connecting line areas CLA include only signal lines. A respective connecting line area of the one or more connecting line areas CLA includes signal lines connecting scan units of adjacent stages and respectively in two adjacent scan unit areas of the plurality of scan unit areas SUA.

In some embodiments, as shown in FIG. 5A to FIG. 5C, the fanout lines FOL connect to the scan circuit through the scan units in the plurality of scan unit areas SUA, and do not directly connect to the one or more connecting line areas CLA. The first connecting interface IF1 is between the first region R1 and the plurality of scan unit areas SUA, and the first connecting interface IF1 is absent in regions corresponding to the one or more connecting line areas CLA.

FIG. 5D illustrates a third region in a display panel in some embodiments according to the present disclosure. Referring to FIG. 5D, the third region R3 in some embodiments includes a plurality of straight line areas SA and one or more curved line areas CA. Signal lines in the plurality of straight line areas SA extend substantially along a same extension direction. Signal lines in the one or more curved line areas CA are curved signal lines. Signal lines in a respective curved line area of the one or more curved line areas CA connect signal lines in two adjacent straight line areas of the plurality of straight line areas SA.

Referring to FIG. 5A, in some embodiments, a respective sub-region of the one or more sub-regions (e.g., the window sub-region WR or the wire-free sub-region WF) of the fourth region R4 is adjacent to a respective curved line area of the one or more curved line areas CA. FIG. 5E illustrates a respective sub-region in a display panel in some embodiments according to the present disclosure. Referring to FIG. 5A to FIG. 5E, two straight line areas of the plurality of straight line areas SA are respectively on a first side S1 and on a second side S2 of the respective sub-region RSR, the first side S1 and the second side S2 being opposite to each other. A respective curved line area of the one or more curved line areas CA is on a third side S3 of the respective sub-region RSR.

In some embodiments, with regard to at least one straight line area of the plurality of straight line areas SA, a first sub-region of the one or more sub-regions is on one side of the at least one straight line area, and a second sub-region of the one or more sub-regions is on an opposite side of the at least one straight line area.

In some embodiments, the plurality of straight line areas SA and the one or more sub-regions are arranged in a same column, e.g., substantially aligned along a same central line.

Referring to FIG. 5A to FIG. 5D, signal lines in the respective curved line area of the one or more curved line areas CA curve around a side (e.g., the third side S3) of the respective sub-region of the one or more sub-regions. Optionally, signal lines in the respective connecting line area of the one or more connecting line areas CLA curve around the signal lines in the respective curved line area of the one or more curved line areas CA.

In some embodiments, the scan circuit has a non-uniform inter-unit distance. Optionally, in a first portion of the scan circuit adjacent to at least one (e.g., 1 or 2) sub-region of the one or more sub-regions, the scan circuit has a first average inter-unit distance; in a second portion of the scan circuit that is not directly adjacent to the one or more sub-regions, the scan circuit has a second average inter-unit distance. The second average inter-unit distance is greater than the first average inter-unit distance.

In some embodiments, the fourth region R4 further includes a margin area MGA on a side of the one or more sub-regions away from the display area DA. The margin area MGA is on a fourth side S4 of the respective sub-region RSR.

In the embodiments depicted in FIG. 5A, an overall smaller bezel area can be achieved as compared to the related display panel. Particularly, by having signal lines in the respective curved line area of the one or more curved line areas CA curve around a side of the respective sub-region of the one or more sub-regions, and having signal lines in the respective connecting line area of the one or more connecting line areas CLA curve around the signal lines in the respective curved line area of the one or more curved line areas CA, the bezel area where the one or more sub-regions are located can be reduced. The margin area MGA provides a margin during a cutting process to form the display panel. By having the margin area MGA, encapsulation reliability of the display panel can be enhanced.

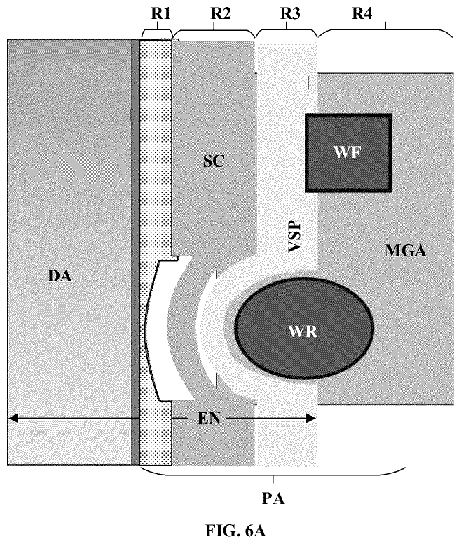

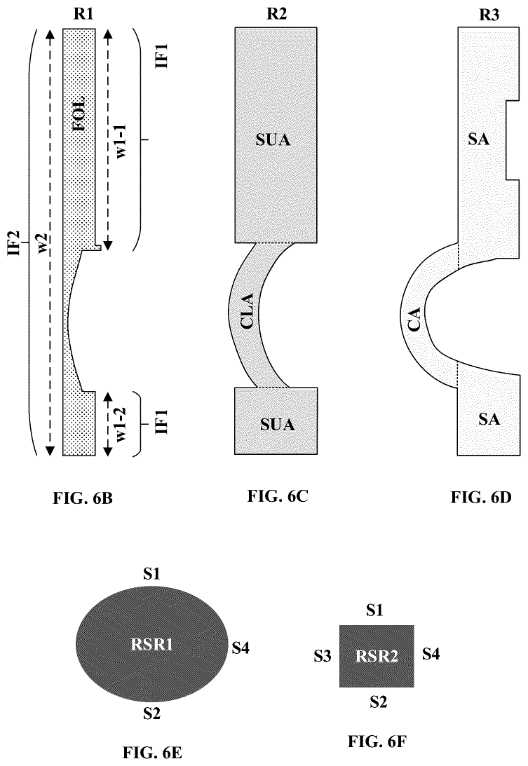

FIG. 6A is a schematic diagram illustrating the structure of a portion of a display panel in some embodiments according to the present disclosure. Referring to FIG. 6A, the peripheral area PA in some embodiments includes a first region R1, a second region R2, a third region R3, and a fourth region R4. The display area DA, the first region R1, the second region R2, and the third region R3 are sequentially arranged along a direction away from the display area DA. Optionally, the display area DA, the first region R1, the second region R2, the third region R3, and the fourth region R4 are sequentially arranged along a direction away from the display area DA. The first region R1 is between the display area DA and the second region R2. The second region R2 is between the first region R1 and the third region R3. The third region R3 is between the second region R2 and the fourth region R4. The first region R1 spaces apart the display area DA and the second region R2. The second region R2 spaces apart the first region R1 and the third region R3. The third region R3 spaces apart the second region R2 and the fourth region R4.

In some embodiments, the second region R2 includes a scan circuit SC. In some embodiments, the third region R3 includes a voltage supply pad configured to provide a voltage supply signal to the subpixels in the display area DA. The first region R1 includes fanout lines FOL connecting the scan circuits to the subpixels in the display area DA. The fourth region R4 includes one or more sub-regions, e.g., a window sub-region WR or a wire-free sub-region WF.

In some embodiments, an encapsulating layer EN extends from the display area DA into the peripheral area PA. The encapsulating layer EN encapsulates light emitting elements and circuits in the display panel. The encapsulating layer EN extends throughout the display area DA. The encapsulating layer EN is at least partially present in the first region R1, the second region R2, and the third region R3. The encapsulating layer EN is at least partially absent (e.g., completely absent) in the fourth region R4.

FIG. 6B illustrates a first region in a display panel in some embodiments according to the present disclosure. Referring to FIG. 6A and FIG. 6B, a first connecting interface IF1 at which fanout lines FOL connect to the scan circuit SC and a second connecting interface IF2 at which fanout lines FOL connect to the display area DA are depicted. A first width of the first connecting interface IF1 is less than the second width w2 of the second connecting interface IF2. The first width is a sum of w1-1 and w1-2 depicted in FIG. 6B. A ratio of the second width w2 to the first width is greater than 1, e.g., greater than 1.1, greater than 1.2, greater than 1.3, greater than 1.4, greater than 1.5, greater than 2.0, greater than 2.5, greater than 3.0, greater than 3.5, greater than 4.0, greater than 4.5, or greater than 5.0.

FIG. 6C illustrates a second region in a display panel in some embodiments according to the present disclosure. Referring to FIG. 6C, the second region R2 in some embodiments includes a plurality of scan unit areas SUA and one or more connecting line areas CLA. The scan circuit includes a plurality of scan units in cascading stages. A respective scan unit of the plurality of scan units includes transistors. The transistors of the scan circuit is absent in the one or more connecting line areas CLA. The one or more connecting line areas CLA include only signal lines. A respective connecting line area of the one or more connecting line areas CLA includes signal lines connecting scan units of adjacent stages and respectively in two adjacent scan unit areas of the plurality of scan unit areas SUA.

In some embodiments, as shown in FIG. 6A to FIG. 6C, the fanout lines FOL connect to the scan circuit through the scan units in the plurality of scan unit areas SUA, and do not directly connect to the one or more connecting line areas CLA. The first connecting interface IF1 is between the first region R1 and the plurality of scan unit areas SUA, and the first connecting interface IF1 is absent in regions corresponding to the one or more connecting line areas CLA.

FIG. 6D illustrates a third region in a display panel in some embodiments according to the present disclosure. Referring to FIG. 6D, the third region R3 in some embodiments includes a plurality of straight line areas SA and one or more curved line areas CA. Signal lines in the plurality of straight line areas SA extend substantially along a same extension direction. Signal lines in the one or more curved line areas CA are curved signal lines. Signal lines in a respective curved line area of the one or more curved line areas CA connect signal lines in two adjacent straight line areas of the plurality of straight line areas SA.

Referring to FIG. 6A, in some embodiments, a first respective sub-region of the one or more sub-regions (e.g., the window sub-region WR) of the fourth region R4 is adjacent to a respective curved line area of the one or more curved line areas CA. FIG. 6E illustrates a first respective sub-region in a display panel in some embodiments according to the present disclosure. Referring to FIG. 6A to FIG. 6E, two straight line areas of the plurality of straight line areas SA are respectively on a first side S1 and on a second side S2 of the first respective sub-region RSR1, the first side S1 and the second side S2 being opposite to each other. A respective curved line area of the one or more curved line areas CA is on a third side S3 of the first respective sub-region RSR1. The fourth region R4 further includes a margin area MGA on a side of a first respective sub-region RSR1 away from the display area DA. The margin area MGA is on a fourth side S4 of the first respective sub-region RSR1.

Referring to FIG. 6A, in some embodiments, a second respective sub-region of the one or more sub-regions (e.g., the wire-free sub-region WF) of the fourth region R4 is adjacent to a respective straight line area of the plurality of straight line areas SA. FIG. 6F illustrates a second respective sub-region in a display panel in some embodiments according to the present disclosure. Referring to FIG. 6A to FIG. 6D and FIG. 6F, the fourth region R4 further includes a margin area MGA on a side of a second respective sub-region RSR2 away from the display area DA. The margin area MGA is on the first side S1, the second side S2, and the fourth side S4 of the second respective sub-region RSR2. A respective straight line area of the plurality of straight line areas SA is on a third side S3 of the second respective sub-region RSR2.

In some embodiments, the plurality of straight line areas SA and at least one of the one or more sub-regions (e.g., at least the window sub-region WR) are arranged in a same column, e.g., substantially aligned along a same central line.

Referring to FIG. 6A to FIG. 6E, signal lines in the respective curved line area of the one or more curved line areas CA curve around a side (e.g., the third side S3) of the first respective sub-region RSR1 of the one or more sub-regions. Optionally, signal lines in the respective connecting line area of the one or more connecting line areas CLA curve around the signal lines in the respective curved line area of the one or more curved line areas CA.

In some embodiments, the scan circuit has a non-uniform inter-unit distance. Optionally, in a first portion of the scan circuit adjacent to at least one (e.g., 1 or 2) sub-region of the one or more sub-regions, the scan circuit has a first average inter-unit distance; in a second portion of the scan circuit that is not directly adjacent to the one or more sub-regions, the scan circuit has a second average inter-unit distance. The second average inter-unit distance is greater than the first average inter-unit distance.

In the embodiments depicted in FIG. 6A, an overall smaller bezel area can be achieved as compared to the related display panel. Particularly, by having signal lines in the respective curved line area of the one or more curved line areas CA curve around a side of the first respective sub-region of the one or more sub-regions, and having signal lines in the respective connecting line area of the one or more connecting line areas CLA curve around the signal lines in the respective curved line area of the one or more curved line areas CA, the bezel area where the one or more sub-regions are located can be reduced. The margin area MGA provides a margin during a cutting process to form the display panel. By having the margin area MGA, encapsulation reliability of the display panel can be enhanced.

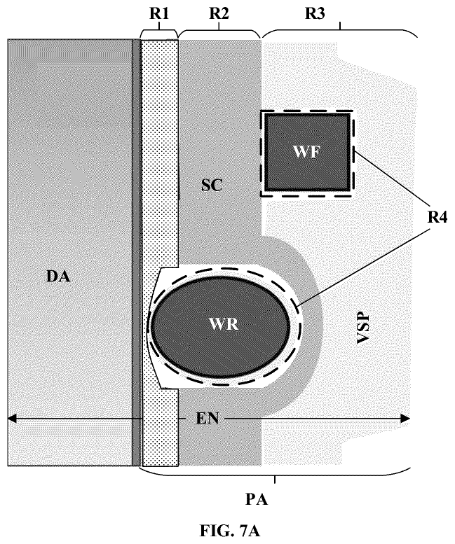

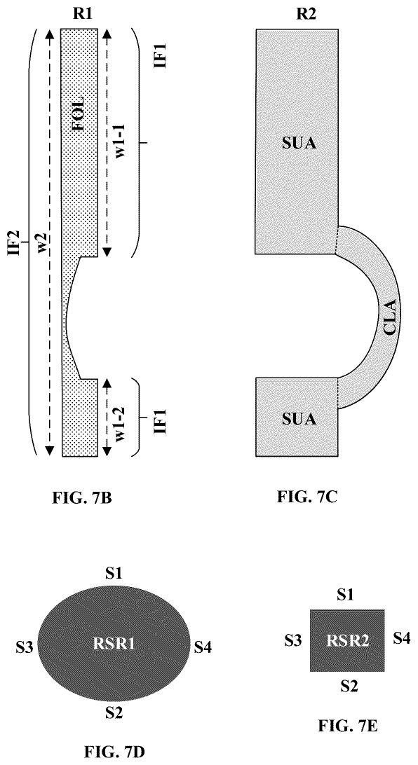

FIG. 7A is a schematic diagram illustrating the structure of a portion of a display panel in some embodiments according to the present disclosure. Referring to FIG. 7A, the peripheral area PA in some embodiments includes a first region R1, a second region R2, a third region R3, and a fourth region R4. The display area DA, the first region R1, the second region R2, and the third region R3 are sequentially arranged along a direction away from the display area DA. The first region R1 is between the display area DA and the second region R2. The second region R2 is between the first region R1 and the third region R3. The first region R1 spaces apart the display area DA and the second region R2. The second region R2 spaces apart the first region R1 and the third region R3.

In some embodiments, the second region R2 includes a scan circuit SC. In some embodiments, the third region R3 includes a voltage supply pad configured to provide a voltage supply signal to the subpixels in the display area DA. The first region R1 includes fanout lines FOL connecting the scan circuits to the subpixels in the display area DA. The fourth region R4 includes one or more sub-regions, e.g., a window sub-region WR or a wire-free sub-region WF.

In some embodiments, an encapsulating layer EN extends from the display area DA into the peripheral area PA. The encapsulating layer EN encapsulates light emitting elements and circuits in the display panel. The encapsulating layer EN extends throughout the display area DA. The encapsulating layer EN is at least partially present in the first region R1, the second region R2, and the third region R3. The encapsulating layer EN is at least partially absent (e.g., completely absent) in the fourth region R4.

FIG. 7B illustrates a first region in a display panel in some embodiments according to the present disclosure. Referring to FIG. 7A and FIG. 7B, a first connecting interface IF1 at which fanout lines FOL connect to the scan circuit SC and a second connecting interface IF2 at which fanout lines FOL connect to the display area DA are depicted. A first width of the first connecting interface IF1 is less than the second width w2 of the second connecting interface IF2. The first width is a sum of w1-1 and w1-2 depicted in FIG. 7B. A ratio of the second width w2 to the first width is greater than 1, e.g., greater than 1.1, greater than 1.2, greater than 1.3, greater than 1.4, greater than 1.5, greater than 2.0, greater than 2.5, greater than 3.0, greater than 3.5, greater than 4.0, greater than 4.5, or greater than 5.0.

FIG. 7C illustrates a second region in a display panel in some embodiments according to the present disclosure. Referring to FIG. 7C, the second region R2 in some embodiments includes a plurality of scan unit areas SUA and one or more connecting line areas CLA. The scan circuit includes a plurality of scan units in cascading stages. A respective scan unit of the plurality of scan units includes transistors. The transistors of the scan circuit is absent in the one or more connecting line areas CLA. The one or more connecting line areas CLA include only signal lines. A respective connecting line area of the one or more connecting line areas CLA includes signal lines connecting scan units of adjacent stages and respectively in two adjacent scan unit areas of the plurality of scan unit areas SUA.

In some embodiments, as shown in FIG. 7A to FIG. 7C, the fanout lines FOL connect to the scan circuit through the scan units in the plurality of scan unit areas SUA, and do not directly connect to the one or more connecting line areas CLA. The first connecting interface IF1 is between the first region R1 and the plurality of scan unit areas SUA, and the first connecting interface IF1 is absent in regions corresponding to the one or more connecting line areas CLA.

Referring to FIG. 7A, in some embodiments, a first respective sub-region of the one or more sub-regions (e.g., the window sub-region WR) of the fourth region R4 is surrounded by a combination of the first region R1 and the second region R2. FIG. 7D illustrates a first respective sub-region in a display panel in some embodiments according to the present disclosure. Referring to FIG. 7A to FIG. 7D, two scan unit areas of the plurality of scan unit areas SUA are respectively on a first side S1 and on a second side S2 of the first respective sub-region RSR1, the first side S1 and the second side S2 being opposite to each other. A portion of the first region R1 is on a third side S3 of the first respective sub-region RSR1, a respective connecting line area of the one or more connecting line areas CLA is on a fourth side S4 of the first respective sub-region RSR1, the third side S3 and the fourth side S4 being opposite to each other.

Referring to FIG. 7A, in some embodiments, a second respective sub-region of the one or more sub-regions (e.g., the wire-free sub-region WF) of the fourth region R4 is adjacent to a respective scan unit area of the plurality of scan unit areas SUA. FIG. 7E illustrates a second respective sub-region in a display panel in some embodiments according to the present disclosure. Referring to FIG. 7A to FIG. 7C, and FIG. 7E, the third region R3 is on the first side S1, the second side S2, and the fourth side S4 of the second respective sub-region RSR2, a respective scan unit area of the plurality of scan unit areas SUA is on a third side S3 of the second respective sub-region RSR2.

In some embodiments, the plurality of scan unit areas SUA and the one or more sub-regions (e.g., the window sub-region WR) are arranged in a same column, e.g., substantially aligned along a same central line.

In some embodiments, signal lines in the respective connecting line area of the one or more connecting line areas CLA curve around the first respective sub-region RSR1 of the one or more sub-regions.

In some embodiments, the scan circuit has a non-uniform inter-unit distance. Optionally, in a first portion of the scan circuit adjacent to at least one (e.g., 1 or 2) sub-region of the one or more sub-regions, the scan circuit has a first average inter-unit distance; in a second portion of the scan circuit that is not directly adjacent to the one or more sub-regions, the scan circuit has a second average inter-unit distance. The second average inter-unit distance is greater than the first average inter-unit distance.

In the embodiments depicted in FIG. 7A, an overall smaller bezel area can be achieved as compared to the related display panel. Particularly, by having the one or more sub-regions disposed in a region between the first region R1 and the second region R2, the bezel area where the one or more sub-regions are located can be reduced.

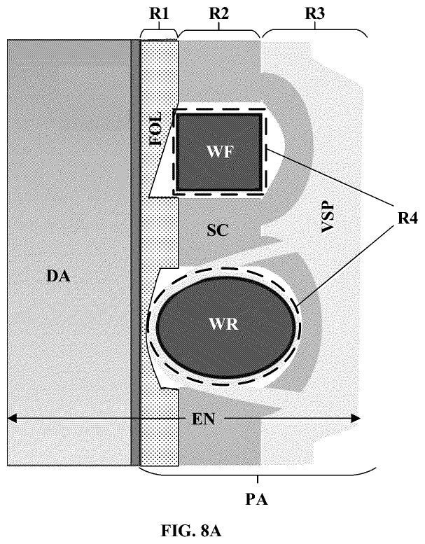

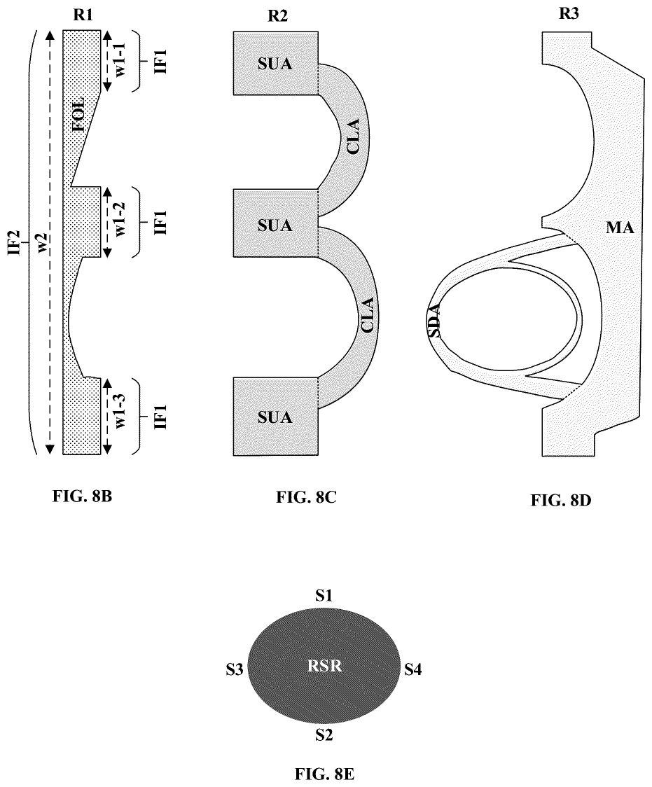

FIG. 8A is a schematic diagram illustrating the structure of a portion of a display panel in some embodiments according to the present disclosure. Referring to FIG. 8A, the peripheral area PA in some embodiments includes a first region R1, a second region R2, a third region R3, and a fourth region R4. The display area DA, the first region R1, the second region R2, and the third region R3 are sequentially arranged along a direction away from the display area DA. The first region R1 is between the display area DA and the second region R2. The second region R2 is between the first region R1 and the third region R3. The first region R1 spaces apart the display area DA and the second region R2. The second region R2 spaces apart the first region R1 and the third region R3.

In some embodiments, the second region R2 includes a scan circuit SC. In some embodiments, the third region R3 includes a voltage supply pad configured to provide a voltage supply signal to the subpixels in the display area DA. The first region R1 includes fanout lines FOL connecting the scan circuits to the subpixels in the display area DA. The fourth region R4 includes one or more sub-regions, e.g., a window sub-region WR or a wire-free sub-region WF.

In some embodiments, an encapsulating layer EN extends from the display area DA into the peripheral area PA. The encapsulating layer EN encapsulates light emitting elements and circuits in the display panel. The encapsulating layer EN extends throughout the display area DA. The encapsulating layer EN is at least partially present in the first region R1, the second region R2, and the third region R3. The encapsulating layer EN is at least partially absent (e.g., completely absent) in the fourth region R4.

FIG. 8B illustrates a first region in a display panel in some embodiments according to the present disclosure. Referring to FIG. 8A and FIG. 8B, a first connecting interface IF1 at which fanout lines FOL connect to the scan circuit SC and a second connecting interface IF2 at which fanout lines FOL connect to the display area DA are depicted. A first width of the first connecting interface IF1 is less than the second width w2 of the second connecting interface IF2. The first width is a sum of w1-1, w1-2, and w1-3 depicted in FIG. 8B. A ratio of the second width w2 to the first width is greater than 1, e.g., greater than 1.1, greater than 1.2, greater than 1.3, greater than 1.4, greater than 1.5, greater than 2.0, greater than 2.5, greater than 3.0, greater than 3.5, greater than 4.0, greater than 4.5, or greater than 5.0.

FIG. 8C illustrates a second region in a display panel in some embodiments according to the present disclosure. Referring to FIG. 8C, the second region R2 in some embodiments includes a plurality of scan unit areas SUA and one or more connecting line areas CLA. The scan circuit includes a plurality of scan units in cascading stages. A respective scan unit of the plurality of scan units includes transistors. The transistors of the scan circuit is absent in the one or more connecting line areas CLA. The one or more connecting line areas CLA include only signal lines. A respective connecting line area of the one or more connecting line areas CLA includes signal lines connecting scan units of adjacent stages and respectively in two adjacent scan unit areas of the plurality of scan unit areas SUA.

In some embodiments, as shown in FIG. 8A to FIG. 8C, the fanout lines FOL connect to the scan circuit through the scan units in the plurality of scan unit areas SUA, and do not directly connect to the one or more connecting line areas CLA. The first connecting interface IF1 is between the first region R1 and the plurality of scan unit areas SUA, and the first connecting interface IF1 is absent in regions corresponding to the one or more connecting line areas CLA.

Referring to FIG. 8A, in some embodiments, a respective sub-region of the one or more sub-regions (e.g., the window sub-region WR or the wire-free sub-region WF) of the fourth region R4 is surrounded by a combination of the first region R1 and the second region R2. FIG. 8E illustrates a respective sub-region in a display panel in some embodiments according to the present disclosure. Referring to FIG. 8A to FIG. 8C, and FIG. 8E, two scan unit areas of the plurality of scan unit areas SUA are respectively on a first side S1 and on a second side S2 of the respective sub-region RSR, the first side S1 and the second side S2 being opposite to each other. A portion of the first region R1 is on a third side S3 of the respective sub-region RSR, a respective connecting line area of the one or more connecting line areas CLA is on a fourth side S4 of the respective sub-region RSR, the third side S3 and the fourth side S4 being opposite to each other.

In some embodiments, with regard to at least one scan unit area of the plurality of scan unit areas SUA, a first sub-region of the one or more sub-regions is on one side of the at least one scan unit area, and a second sub-region of the one or more sub-regions is on an opposite side of the at least one scan unit area.

In some embodiments, the plurality of scan unit areas SUA and the one or more sub-regions are arranged in a same column, e.g., substantially aligned along a same central line.

In some embodiments, signal lines in the respective connecting line area of the one or more connecting line areas CLA curve around the respective sub-region of the one or more sub-regions.

In some embodiments, the scan circuit has a non-uniform inter-unit distance. Optionally, in a first portion of the scan circuit adjacent to at least one (e.g., 1 or 2) sub-region of the one or more sub-regions, the scan circuit has a first average inter-unit distance; in a second portion of the scan circuit that is not directly adjacent to the one or more sub-regions, the scan circuit has a second average inter-unit distance. The second average inter-unit distance is greater than the first average inter-unit distance.

FIG. 8D illustrates a third region in a display panel in some embodiments according to the present disclosure. Referring to FIG. 8D, the third region R3 in some embodiments includes a main area MA and a surrounding area SDA. The main area MA is on a side of the second region R2 away from the display area DA. The surrounding area SDA substantially surrounds a first respective sub-region of the one or more sub-regions (e.g., the window sub-region WR in FIG. 8A). As used herein the term “substantially surrounding” refers to surrounding at least 50% (e.g., at least 60%, at least 70%, at least 80%, at least 90%, at least 95%, at least 99%, and 100%) of a perimeter of an area. In one example, the encapsulating layer EN is at least partially present in the surrounding area SDA. In another example, the voltage supply pad VSP is at least partially present in the surrounding area SDA. In another example, both the encapsulating layer EN and the voltage supply pad VSP are at least partially present in the surrounding area SDA.

In the embodiments depicted in FIG. 8A, an overall smaller bezel area can be achieved as compared to the related display panel. Particularly, by having the one or more sub-regions disposed in a region between the first region R1 and the second region R2, the bezel area where the one or more sub-regions are located can be reduced. By having the voltage supply pad passing through a surrounding area SDA, the bezel area can be further reduced.

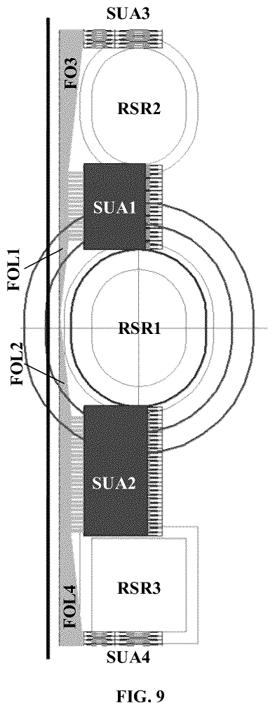

FIG. 9 is a schematic diagram illustrating a layout of fanout lines relative to one or more sub-regions in a display panel in some embodiments according to the present disclosure. Referring to FIG. 9, in some embodiments, the second region includes a plurality of scan unit areas including a first scan unit area SUA1, a second scan unit area SUA2, a third scan unit area SUA3, and a fourth scan unit area SUA4; and the fourth region includes one or more sub-regions including a first respective sub-region RSR1, a second respective sub-region RSR2, and a third respective sub-region RSR3. As shown in FIG. 9, in some embodiments, the fanout lines includes multiple first fanout lines FOL1 and multiple second fanout lines FOL2. The multiple first fanout lines FOL1 and the multiple second fanout lines FOL2 space apart the first respective sub-region RSR1 from the display area. The multiple first fanout lines FOL1 transmit multiple control signals output from multiple stages of scan units in the first scan unit area SUA1 to corresponding rows of subpixels in the display area. The multiple second fanout lines FOL2 transmit multiple control signals output from multiple stages of scan units in the second scan unit area SUA2.

In some embodiments, to accommodate the first respective sub-region RSR1, the first scan unit area SUA1 and the second scan unit area SUA2 have a reduced inter-unit distance, e.g., an average distance between adjacent scan units in the first scan unit area SUA1 and the second scan unit area SUA2 is reduced. Control signals for rows of subpixels where the first respective sub-region RSR1 is located are provided in part by the first scan unit area SUA1 and in part by the second scan unit area SUA2. The multiple first fanout lines FOL1 and the multiple second fanout lines FOL2 transmit control signals to rows of subpixels where the first respective sub-region RSR1 is located, from the first scan unit area SUA1 and the second scan unit area SUA2, respectively.

In some embodiments, the multiple first fanout lines FOL1 and the multiple second fanout lines FOL2 have a mirror symmetry or a pseudo mirror symmetry with regard to a mirror symmetry plane or a pseudo mirror symmetry plane of the first respective sub-region RSR1. This layout is particularly conducive to minimizing the distance between the first respective sub-region RSR1 and the display area, when the first respective sub-region RSR1 is adjacent to other sub-regions (e.g., the second respective sub-region RSR2 and the third respective sub-region RSR3).

Referring to FIG. 9, in some embodiments, the fanout lines includes multiple third fanout lines FOL3. The multiple third fanout lines FOL3 space apart the second respective sub-region RSR2 from the display area. The multiple third fanout lines FOL3 transmit multiple control signals output from multiple stages of scan units in the third scan unit area SUA3 to corresponding rows of subpixels in the display area.

In some embodiments, to accommodate the second respective sub-region RSR2, the third scan unit area SUA3 has a reduced inter-unit distance, e.g., an average distance between adjacent scan units in the third scan unit area SUA3 is reduced. Control signals for rows of subpixels where the second respective sub-region RSR2 is located are provided by the third scan unit area SUA3. The multiple third fanout lines FOL3 transmit control signals to rows of subpixels where the second respective sub-region RSR2 is located, from the third scan unit area SUA3.

In some embodiments, the multiple third fanout lines FOL3 lack a mirror symmetry or a pseudo mirror symmetry with regard to a mirror symmetry plane or a pseudo mirror symmetry plane of the second respective sub-region RSR2.

Referring to FIG. 9, in some embodiments, the fanout lines includes multiple fourth fanout lines FOL4. The multiple fourth fanout lines FOL4 space apart the third respective sub-region RSR3 from the display area. The multiple fourth fanout lines FOL4 transmit multiple control signals output from multiple stages of scan units in the fourth scan unit area SUA4 to corresponding rows of subpixels in the display area.

In some embodiments, to accommodate the third respective sub-region RSR3, the fourth scan unit area SUA4 has a reduced inter-unit distance, e.g., an average distance between adjacent scan units in the fourth scan unit area SUA4 is reduced. Control signals for rows of subpixels where the third respective sub-region RSR3 is located are provided by the fourth scan unit area SUA4. The multiple fourth fanout lines FOL4 transmit control signals to rows of subpixels where the third respective sub-region RSR3 is located, from the fourth scan unit area SUA4.

In some embodiments, the multiple fourth fanout lines FOL4 lack a mirror symmetry or a pseudo mirror symmetry with regard to a mirror symmetry plane or a pseudo mirror symmetry plane of the third respective sub-region RSR3.

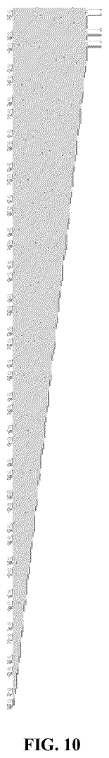

FIG. 10 illustrates an overall shape of multiple fanout lines in a portion of a first region in a display panel in some embodiments according to the present disclosure. The multiple fanout lines depicted in FIG. 10 may be the multiple first fanout lines FOL1, the multiple second fanout lines FOL2, the multiple third fanout lines FOL3, or the multiple fourth fanout lines FOL4 depicted in FIG. 9. Referring to FIG. 9 and FIG. 10, the multiple fanout lines in the portion of a first region have an overall shape tapering from a wider end to a narrower end. The wider end corresponds to where the respective sub-region is more spaced apart from the display area. The narrower end corresponds to where the respective sub-region is closer to the display area.

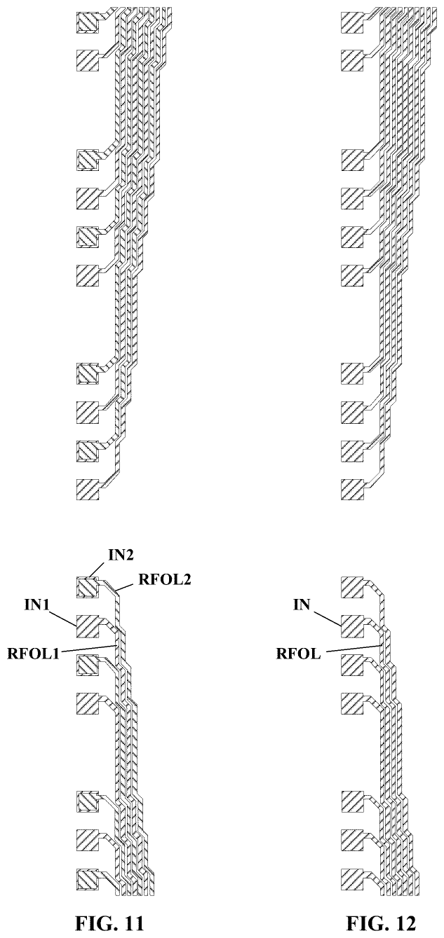

FIG. 11 illustrates the structure of multiple fanout lines in a portion of a first region in a display panel in some embodiments according to the present disclosure. The multiple fanout lines depicted in FIG. 11 may correspond to the multiple first fanout lines FOL1 and the multiple second fanout lines FOL2 depicted in FIG. 9. In some embodiments, the multiple fanout lines include a plurality of first fanout lines RFOL1 in a first layer and a plurality of second fanout lines RFOL2 in a second layer. The second layer is different from the first layer. A respective first fanout line of the plurality of first fanout lines RFOL1 is connected to a respective first input terminal IN1, and configured to transmit a control signal to a respective first row of subpixel through the respective first input terminal IN1. A respective second fanout line of the plurality of second fanout lines RFOL2 is connected to a respective second input terminal IN2, and configured to transmit a control signal to a respective second row of subpixel through the respective second input terminal IN2.

In some embodiments, the plurality of first fanout lines RFOL1 in the first layer and the plurality of second fanout lines RFOL2 in the second layer are alternately arranged. By having the plurality of first fanout lines RFOL1 and the plurality of second fanout lines RFOL2 alternately in two different layers, an area occupied by the fanout lines can be further reduced.

The fanout lines may be disposed in various appropriate layers. In some embodiments, the first layer and the second layer are two different layers selected from the group consisting of a first conductive layer, a second conductive layer, a first signal line layer, and a second signal line layer.

In FIG. 11, an orthographic projection of a respective first fanout line of the plurality of first fanout lines RFOL1 on a base substrate is non-overlapping with an orthographic projection of a respective second fanout line of the plurality of second fanout lines RFOL2 on the base substrate.

Alternatively, in some other embodiments, an orthographic projection of a respective first fanout line of a plurality of first fanout lines on a base substrate is at least partially overlapping with an orthographic projection of a respective second fanout line of a plurality of second fanout lines on the base substrate. By having partially overlapping fanout lines, an area occupied by the fanout lines can be further reduced.

FIG. 12 illustrates the structure of multiple fanout lines in a portion of a first region in a display panel in some embodiments according to the present disclosure. Referring to FIG. 12, in some embodiments, the multiple fanout lines include a plurality of fanout lines RFOL in a same layer. A respective fanout line of the plurality of fanout lines RFOL is connected to a respective input terminal IN, and configured to transmit a control signal to a respective row of subpixel through the respective input terminal IN.

The fanout lines may be disposed in various appropriate layers. In some embodiments, the plurality of fanout lines RFOL are in a layer selected from the group consisting of a first conductive layer, a second conductive layer, a first signal line layer, and a second signal line layer.

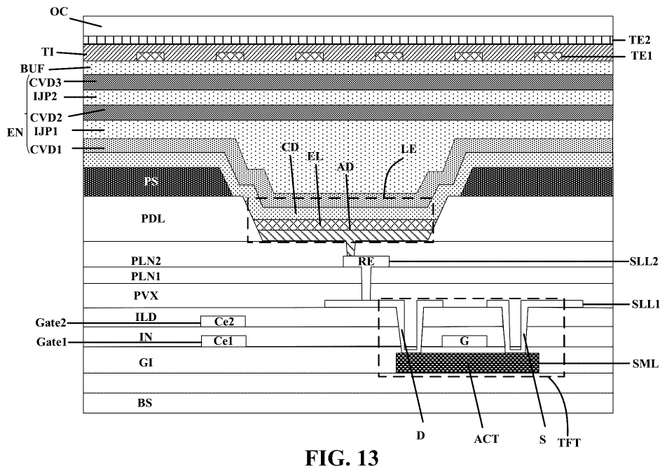

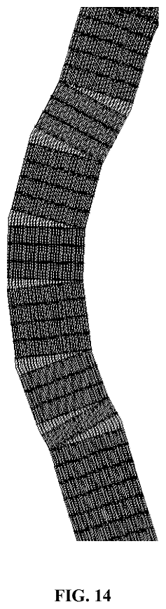

FIG. 13 illustrates a detailed structure in a display area in a display apparatus in some embodiments according to the present disclosure. Referring to FIG. 13, the display apparatus in the display area in some embodiments includes a base substrate BS (e.g., a flexible base substrate); an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first gate metal layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second gate metal layer) on a side of the insulating layer IN away from the gate insulating layer GI; an inter-layer dielectric layer ILD on a side of the second capacitor electrode Ce2 away from the gate insulating layer GI; a source electrode S and a drain electrode D (parts of a first SD metal layer) on a side of the inter-layer dielectric layer ILD away from the gate insulating layer GI; a passivation layer PVX on a side of the source electrode S and the drain electrode D away from the inter-layer dielectric layer ILD; a first planarization layer PLN1 on a side of the passivation layer PVX away from the inter-layer dielectric layer ILD; a relay electrode RE (part of a second SD metal layer) on side of the first planarization layer PLN1 away from the passivation layer PVX; a second planarization layer PLN2 on a side of the relay electrode RE away from the first planarization layer PLN1; a pixel definition layer PDL defining a subpixel aperture and on a side of the second planarization layer PLN2 away from the base substrate BS; and a light emitting element LE in the subpixel aperture. The light emitting element LE includes an anode AD on a side of the second planarization layer PLN2 away from the first planarization layer PLN1; a light emitting layer EL on a side of the anode AD away from the second planarization layer PLN2; and a cathode layer CD on a side of the light emitting layer EL away from the anode AD. The display apparatus in the display area further includes an encapsulating layer EN encapsulating the light emitting element LE, and on a side of the cathode layer CD away from the base substrate BS.

The encapsulating layer EN in some embodiments includes a first inorganic encapsulating sub-layer CVD1 on a side of the cathode layer CD away from the base substrate BS, a first organic encapsulating sub-layer IJP1 on a side of the first inorganic encapsulating sub-layer CVD1 away from the base substrate BS, a second inorganic encapsulating sub-layer CVD2 on a side of the first organic encapsulating sub-layer IJP1 away from the base substrate BS, a second organic encapsulating sub-layer IJP2 on a side of the second inorganic encapsulating sub-layer CVD2 away from the base substrate BS, and a third inorganic encapsulating sub-layer CVD3 on a side of the second organic encapsulating sub-layer IJP2 away from the base substrate BS.

The display apparatus in the display area further includes a buffer layer BUF on a side of the encapsulating layer EN away from the base substrate BS; a first touch electrode layer TE1 on a side of the buffer layer BUF away from the encapsulating layer EN; a touch insulating layer TI on a side of the first touch electrode layer TE1 away from the buffer layer BUF; a second touch electrode layer TE2 on a side of the touch insulating layer TI away from the buffer layer BUF; and an overcoat layer OC on a side of the second touch electrode layer TE2 away from the touch insulating layer TI.

Referring to FIG. 13, the display apparatus includes a semiconductor material layer SML, a first gate metal layer Gate1, a second gate metal layer Gate2, a first signal line layer SLL1, and a second signal line layer SLL2. The display apparatus further includes an insulating layer IN between the first gate metal layer Gate1 and the second gate metal layer Gate2; an inter-layer dielectric layer ILD between the second gate metal layer Gate2 and the first signal line layer SLL1; and at least a passivation layer PVX or a planarization layer PLN between the first signal line layer SLL1 and the second signal line layer SLL2.

FIG. 14 illustrates the structure of curved signal lines in a portion of a first region in a display panel in some embodiments according to the present disclosure. The curved signal lines in FIG. 14 may be signal lines in, for example, the one or more connecting line areas in the second region (see, e.g., CLA in FIG. 6C) or the one or more curved line areas in the third region (see, e.g., CA in FIG. 6D). A respective curved signal line of the curved signal lines may include a plurality of segments connected together, while at least one segment of the plurality of segments is a straight signal line. A combination of the plurality of segments forms the respective curved signal line.

In one example, the curved signal lines are in a same layer.

In another example, the curved signal lines may include signal lines in different layers. In another example, the curved signal lines may include signal lines alternately arranged in two layers. By having signal lines in different layers, an area occupied by the curved signal lines may be reduced.

In another example, at least one respective curved signal line includes two layers of signal lines, orthographic projections of the two layers of signal lines on a base substrate at least partially overlap with each other. By having a two-layer structure, risk of line break may be reduced.

In another example, at least one respective curved signal line includes one single layer of signal line.

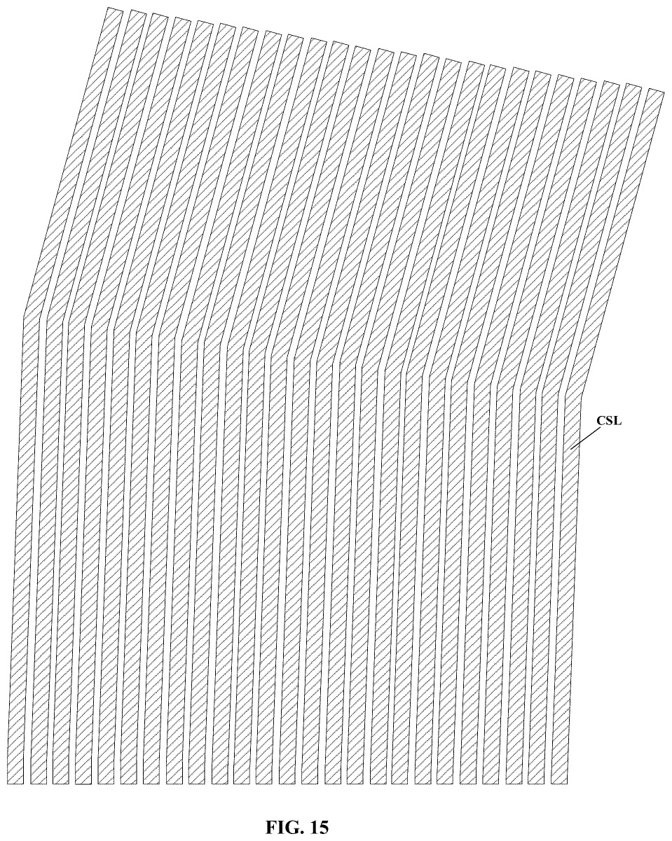

FIG. 15 illustrates the structure of curved signal lines in a portion of a first region in a display panel in some embodiments according to the present disclosure. The curved signal lines in FIG. 15 may be signal lines in, for example, the one or more connecting line areas in the second region (see, e.g., CLA in FIG. 6C) or the one or more curved line areas in the third region (see, e.g., CA in FIG. 6D). Referring to FIG. 15, a respective curved signal line of the curved signal lines CSL may include a plurality of segments connected together, while at least one segment of the plurality of segments is a straight signal line. A combination of the plurality of segments forms the respective curved signal line. In FIG. 15, the curved signal lines CSL are in a same layer, e.g., a layer selected from the group consisting of a first conductive layer, a second conductive layer, a first signal line layer, and a second signal line layer.

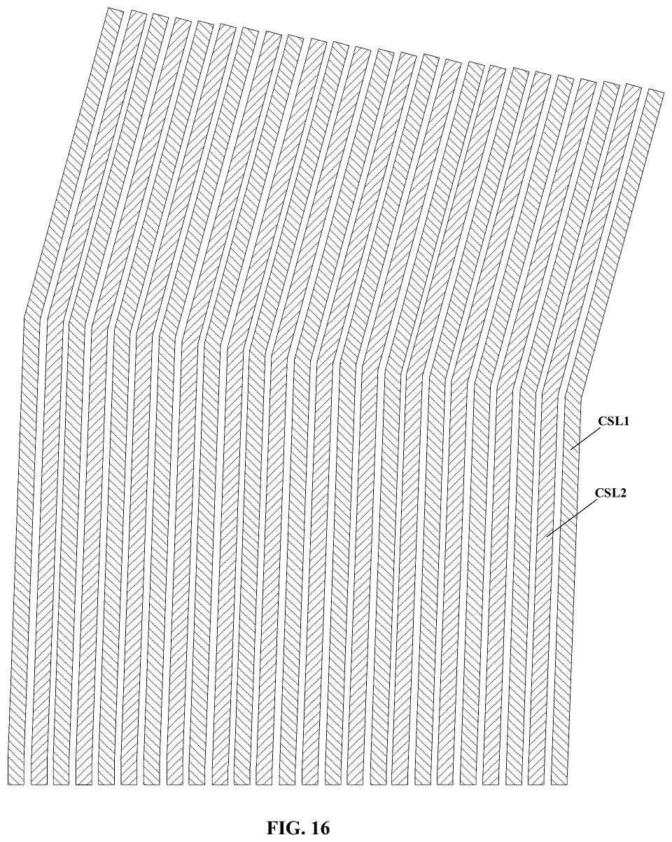

FIG. 16 illustrates the structure of curved signal lines in a portion of a first region in a display panel in some embodiments according to the present disclosure. The curved signal lines in FIG. 16 may be signal lines in, for example, the one or more connecting line areas in the second region (see, e.g., CLA in FIG. 6C) or the one or more curved line areas in the third region (see, e.g., CA in FIG. 6D). Referring to FIG. 16, the curved signal lines includes a plurality of first curved signal lines in a first layer and a plurality of second curved signal lines in a second layer. The second layer is different from the first layer. In some embodiments, the first layer and the second layer are two different layers selected from the group consisting of a first conductive layer, a second conductive layer, a first signal line layer, and a second signal line layer.

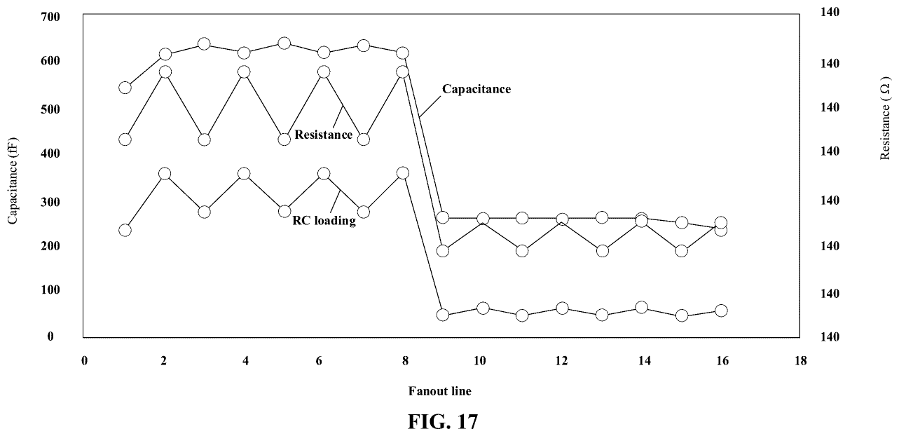

As discussed in text associated with FIG. 9, in some embodiments, multiple fanout lines spacing apart a respective sub-region from the display area is asymmetric with regard to a mirror symmetry plane or a pseudo mirror symmetry plane of the respective sub-region. The multiple fanout lines in the portion of a first region have an overall shape tapering from a wider end to a narrower end. As illustrated in FIG. 9, the multiple third fanout lines FOL3 lack a mirror symmetry or a pseudo mirror symmetry with regard to a mirror symmetry plane or a pseudo mirror symmetry plane of the second respective sub-region RSR2. The inventors of the present disclosure discover that the fanout lines in this layout have different loading. FIG. 17 illustrates different loading in different fanout lines in some embodiments according to the present disclosure. As shown in FIG. 17, fanout lines 1-8 have different capacitance, different resistance, and different RC loading from fanout lines 9-16. The different RC loading leads to risk of mura in the display panel.

In some embodiments, the display panel further includes a compensation circuit configured to compensate the different RC loading in at least one fanout line of the fanout lines.

In another aspect, the present disclosure provides a display apparatus including the display panel described herein or fabricated by a method described herein, and one or more integrated circuits connected to the display panel. Examples of appropriate display apparatuses include, but are not limited to, an electronic paper, a mobile phone, a tablet computer, a television, a monitor, a notebook computer, a digital album, a GPS, etc. Optionally, the display apparatus is an organic light emitting diode display apparatus. Optionally, the display apparatus is a mini light emitting diode display apparatus. Optionally, the display apparatus is a micro light emitting diode display apparatus.

In another aspect, the present disclosure provides a method of fabricating a display panel having a display area and a peripheral area. In some embodiments, the method includes forming a first region, a second region, a third region, and a fourth region of the peripheral area. Optionally, the method further includes forming, in the second region, a scan circuit configured to generate control signals for subpixels in the display area. Optionally, the method further includes forming, in the third region, a voltage supply pad configured to provide a voltage supply signal to the subpixels in the display area. Optionally, the method further includes forming, in the first region, fanout lines connecting the scan circuit to the subpixels in the display area. Optionally, the fourth region includes one or more sub-regions.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A display panel having a display area and a peripheral area, wherein the peripheral area comprises a first region, a second region, a third region, and a fourth region;
the second region comprises a scan circuit configured to generate control signals for subpixels in the display area;
the third region comprises a voltage supply pad configured to provide a voltage supply signal to the subpixels in the display area;
the first region comprises fanout lines connecting the scan circuit to the subpixels in the display area; and
the fourth region comprises one or more sub-regions.

2. The display panel of claim 1, wherein the fanout lines connect to the scan circuit at a first connecting interface and connect to the display area at a second connecting interface; and
a first width of the first connecting interface is less than a second width of the second connecting interface.

3. The display panel of claim 1, wherein the scan circuit has a non-uniform inter-unit distance;
in a first portion of the scan circuit adjacent to at least one sub-region of the one or more sub-regions, the scan circuit has a first average inter-unit distance;
in a second portion of the scan circuit that is not directly adjacent to the one or more sub-regions, the scan circuit has a second average inter-unit distance; and
the second average inter-unit distance is greater than the first average inter-unit distance.

4. The display panel of claim 1, wherein the second region comprises a plurality of scan unit areas and one or more connecting line areas;
the scan circuit comprises a plurality of scan units in cascading stages;
a respective scan unit of the plurality of scan units comprises transistors;
the transistors of the scan circuit is absent in the one or more connecting line areas;
the one or more connecting line areas comprises only signal lines;
a respective connecting line area of the one or more connecting line areas comprises signal lines connecting scan units of adjacent stages and respectively in two adjacent scan unit areas of the plurality of scan unit areas.

5. The display panel of claim 4, wherein the fanout lines connect to the scan circuit through the plurality of scan units in the plurality of scan unit areas, and do not directly connect to the one or more connecting line areas;
a first connecting interface is between the first region and the plurality of scan unit areas; and
the first connecting interface is absent in regions corresponding to the one or more connecting line areas.

6. The display panel of claim 1, wherein at least one sub-region of the one or more sub-regions of the fourth region is surrounded by a combination of the first region and the second region.

7. The display panel of claim 4, wherein two scan unit areas of the plurality of scan unit areas are respectively on a first side and on a second side of a respective sub-region of the one or more sub-regions, the first side and the second side being opposite to each other; and
a portion of the first region is on a third side of the respective sub-region, a respective connecting line area of the one or more connecting line areas is on a fourth side of the respective sub-region, the third side and the fourth side being opposite to each other.

8. The display panel of claim 4, wherein a first sub-region of the one or more sub-regions is on one side of at least one scan unit area of the plurality of scan unit areas; and
a second sub-region of the one or more sub-regions is on an opposite side of the at least one scan unit area.

9. The display panel of claim 4, wherein the plurality of scan unit areas and at least one of the one or more sub-regions are arranged in a same column.

10. The display panel of claim 4, wherein signal lines in the respective connecting line area of the one or more connecting line areas curve around at least one sub-region of the one or more sub-regions.

11. The display panel of claim 4, wherein the one or more sub-regions comprise a first respective sub-region and a second respective sub-region;
the first respective sub-region is surrounded by a combination of the first region and the second region;
two scan unit areas of the plurality of scan unit areas are respectively on a first side and on a second side of the first respective sub-region, the first side and the second side being opposite to each other;
a portion of the first region is on a third side of the first respective sub-region;
a respective connecting line area of the one or more connecting line areas is on a fourth side of the first respective sub-region, the third side and the fourth side being opposite to each other;
the third region is on a first side, a second side, and a fourth side of the second respective sub-region; and
a respective scan unit area of the plurality of scan unit areas is on a third side of the second respective sub-region.

12. The display panel of claim 4, wherein the third region comprises a main area and a surrounding area;
the main area is on a side of the second region away from the display area;
the one or more sub-regions comprises a first respective sub-region;
the surrounding area substantially surrounds the first respective sub-region; and
the voltage supply pad are at least partially present in the surrounding area.

13. The display panel of claim 1, wherein the third region comprises a plurality of straight line areas and one or more curved line areas;
signal lines in the plurality of straight line areas extend substantially along a same extension direction;
signal lines in the one or more curved line areas are curved signal lines; and
signal lines in a respective curved line area of the one or more curved line areas connect signal lines in two adjacent straight line areas of the plurality of straight line areas.

14. The display panel of claim 13, wherein two straight line areas of the plurality of straight line areas are respectively on a first side and on a second side of a respective sub-region of the one or more sub-regions, the first side and the second side being opposite to each other; and
a respective curved line area of the one or more curved line areas is on a third side of the respective sub-region.

15. The display panel of claim 13, wherein a first sub-region of the one or more sub-regions is on one side of at least one straight line area of the plurality of straight line areas; and
a second sub-region of the one or more sub-regions is on an opposite side of the at least one straight line area.

16. The display panel of claim 13, wherein the plurality of straight line areas and at least one of the one or more sub-regions are arranged in a same column.

17. The display panel of claim 13, wherein signal lines in the respective curved line area of the one or more curved line areas curve around a side of at least one sub-region of the one or more sub-regions; and
signal lines in a respective connecting line area of the one or more connecting line areas curve around the signal lines in the respective curved line area of the one or more curved line areas.

18. The display panel of claim 13, wherein the one or more sub-regions comprise a first respective sub-region and a second respective sub-region;
two straight line areas of the plurality of straight line areas are respectively on a first side and on a second side of the first respective sub-region, the first side and the second side being opposite to each other;
a respective curved line area of the one or more curved line areas is on a third side of the first respective sub-region;
the fourth region further comprises a margin area on a side of the first respective sub-region and the second respective sub-region away from the display area;
the margin area is on a fourth side of the first respective sub-region;
the margin area is on a first side, a second side, and a fourth side of the second respective sub-region; and
a respective straight line area of the plurality of straight line areas is on a third side of the second respective sub-region.

19. The display panel of claim 1, further comprising an encapsulating layer extending from the display area into the peripheral area;
wherein the encapsulating layer encapsulates light emitting elements and circuits in the display panel;
the encapsulating layer extends throughout the display area;
the encapsulating layer is at least partially present in the first region, the second region, and the third region; and
the encapsulating layer is at least partially absent in the fourth region.

20. (canceled)

21. A display apparatus, comprising the display panel of claim 1, and one or more integrated circuits connected to the display panel.
